(19) United States
(12) Patent Application Publication
(10) Pub. No.: US 2008/0126653 A1
(43) Pub. Date: May 29, 2008

(54) PORTABLE WEB SERVER WITH USB PORT

(75) Inventors: Andrew E. King, Portland, OR (US); Korey Calmettes, Beaverton, OR (US)

Correspondence Address: PERKINS COIE LLP;PATENT-SEA, P.O. BOX 1247, SEATTLE, WA, 98111-1247, US

(73) Assignee: Icon Global, Ltd., Kingston Chambers (VG)

(21) Appl. No.: 11/564,819

(22) Filed: Nov. 29, 2006

(51) Int. Cl. G06F 13/00; H05K 7/10

(52) U.S. Cl. 710/300; 710/304

(57) ABSTRACT

A portable web server that is connectable to a terminal through a USB port. The terminal is any device that can make HTTP requests to and receive HTTP responses from the portable web server. The portable web server includes a web server program and one or more web application programs. When the web server is connected to the terminal, a user of the terminal or an application on the terminal may access the web application that is contained on the portable web server. The web application is accessed using a web browser on the terminal. Data may be stored in a data storage area on the portable web server. The portable web server may be disconnected from the terminal and moved to a different terminal.

### BACKGROUND

Installing software on computers can be a challenging task for users. Although installation wizards and other applications that lead a user through the installation in a step-by-step fashion have been created to make the installation task easier, the process can still be a frustrating one. Perhaps the greatest installation frustration is when the installation fails. Failures can result from irregularities in the computer on which the software is being installed, such as the existence or absence of certain hardware, software drivers, or settings. Failures can also result from a user's improper response to questions that are asked by the wizard, such as requests to specify certain technical information about the computer on which installation is taking place. Failures can even result from errors in the installation wizard itself. Even if a user is successful in installing the software, once the software is correctly installed it must be adequately maintained. Upgrades, patches, and other fixes must periodically be installed in order to correct errors in the software or to access new and improved software features.

As a result of the difficulties in installing and maintaining software, there has been a recent trend towards web applications. Web applications are applications that are centrally located on one or more web servers, and accessed by a user using a web browser over a network such as the Internet or an intranet. Web applications have become increasingly popular because the application software does not have to be distributed or installed on a local machine. The application software may also be easily updated to fix errors in the software or to provide enhanced capabilities.

There are certain limitations to web applications, however, that have restricted their universal adoption and use. One limitation is that web applications typically require a broadband data connection that is highly reliable. If the connection fails for a period of time, users are unable to access and use the application. Another limitation is that users often feel that the use of a remote application may be less secure than using an application that is on the user's computer. While the actual security issues may be more perceptual than actual, users often feel more comfortable when they retain physical possession of software and the data associated with the software. In certain applications where security of confidentiality is very important, users may therefore opt to use locally-installed software rather than use a web application.

As suggested from the discussion above, locally-installed software and remotely-installed web applications may offer a sub-optimal user experience in certain use cases. It would therefore be beneficial to identify new technology that allows a user to avoid the detriments associated with loading and using application software on a local computer, while at the same time receiving certain benefits of web applications in a secure fashion.

### BRIEF DESCRIPTION OF THE DRAWINGS

FIG. 1 is a perspective diagram of a portable web server having a USB port that may be coupled to a terminal.

FIG. 2 is a block diagram of a hardware architecture for a portable web server.

FIG. 3 is a block diagram of a software architecture for a portable web server.

FIG. 4 is a block diagram of an architecture for a terminal that may be connected to a portable web server.

FIG. 5A is a flow chart of a method for managing packets received from a portable web server or a terminal.

FIG. 5B is a flow chart of a method for managing packets transmitted from a portable web server or a terminal.

FIG. 6 is a perspective diagram of a time clock environment in which a portable web server may be used.

### DETAILED DESCRIPTION

A portable web server that may be directly connected to a terminal is disclosed. The terminal may be a laptop computer, personal computer, dedicated device, or any device that can make HTTP requests to and receive HTTP responses from the portable web server. The portable web server includes a web server program and one or more web application programs. When the web server is connected to the terminal, a user of the terminal or an application on the terminal may access the web application that is contained on the portable web server. The web application is accessed using a browser or other application program on the terminal. Data may be stored in a data storage area on the portable web server or in the memory of the terminal. The portable web server may be disconnected from the terminal and moved to a different terminal. The portable web server thereby allows secure and simple access to a desired web application and data from any terminal having a browser.

In some embodiments, the portable web server includes a USB port to connect the portable web server to a USB port on the terminal. HTTP requests and responses are routed through the USB port to access the web server program. Use of a USB port enables the portable web server to be easily moved from terminal to terminal with a minimal amount of effort by a user. Use of a USB port also ensures broad accessibility to the web application and data on the portable data server, as most terminals have one or more USB ports.

In some embodiments, a software or firmware communication module is provided to prepare TCP/IP-formatted packets for communication over a universal serial bus (USB) communication link. Sending TCP/IP-formatted packets over a USB connection link allows the portable web server to more easily connect to a variety of terminals.

The following description provides specific details for a thorough understanding of, and enabling description for, various embodiments of the technology. One skilled in the art will understand that the technology may be practiced without these details. In some instances, well-known structures and functions have not been shown or described in detail to avoid unnecessarily obscuring the description of the embodiments of the technology. It is intended that the terminology used in the description presented below be interpreted in its broadest reasonable manner, even though it is being used in conjunction with a detailed description of certain embodiments of the technology. Although certain terms may be emphasized below, any terminology intended to be interpreted in any restricted manner will be overtly and specifically defined as such in this Detailed Description section.

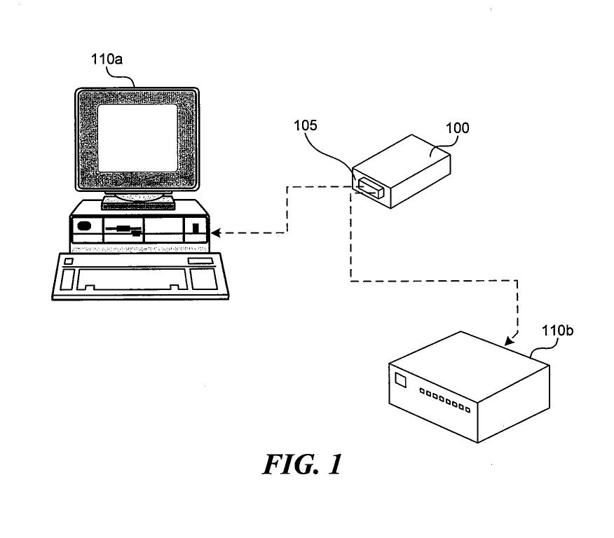

FIG. 1 is a perspective view of an environment in which a portable web server 100 may be used. The portable web server includes a universal serial bus (USB) port 105, depicted as a male USB connector although a female connector could be used in certain circumstances. The USB port allows the portable web server to be simply and easily connected to a terminal 110, such as a personal computer 110A or other computer device 110B. The term “terminal” is used broadly herein to describe to refer to any device that may send HTTP requests and receive HTTP responses from the portable web server. As a result, terminals may include, but not be limited to, laptop computers, portable computers, server computers, personal digital assistants (PDAs), mobile devices (e.g., mobile phones) and other types of computers. As will be described in additional detail below, the portable web server 100 contains a web application that may be accessed by users of the terminal or by an application that is operating on the terminal. The web application and/or any data stored on the portable web server may therefore be easily shared between terminals.

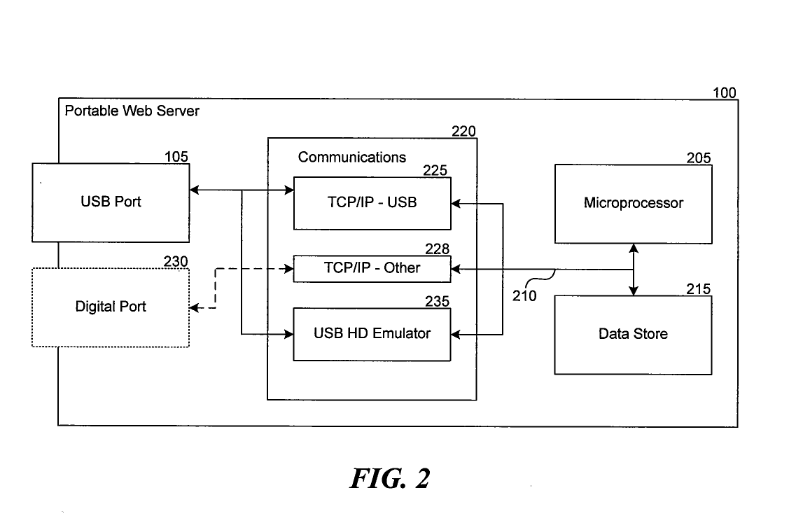

FIG. 2 is a block diagram of various components that are contained within the portable web server 100. A microprocessor 205 is connected by a data bus 210 to a data store 215. The type of microprocessor 205 used in the web server depends, in part, on the desired size of the web server and the complexity of the web application that is to be installed on the web server. In some embodiments, the microprocessor may be an ARM processor, such as a processor from the ARM7 or ARM9 families of processors that are produced under license from ARM Ltd., or a processor from the XScale family of processors that are manufactured by Intel Corporation. The type of technology used to implement the data store 215 may similarly be selected and sized depending on the desired application or applications that are provided on the web server. Since the portable web server does not have an integral power supply, the technology used to implement at least a portion of the data store should preferably be capable of retaining information during periods of no power. For example, portions of the data store may be comprised of non-volatile storage such as read-only memory (ROM), flash memory, magnetic computer storage devices such as hard disks, floppy disks, and magnetic tape, or other types of non-volatile memory. Those skilled in the art will appreciate, of course, that portions of the memory may comprise volatile memory. Such volatile memory, such as random-access memory (RAM), may only be used when power is applied to the portable web server. In some embodiments, a battery backup may be provided in the portable web server to provide power to some components when the web server is not otherwise plugged into a terminal. The size of the memory may be selected based on the particular web applications that are being offered. Certain applications may require greater memory storage, whereas certain applications may require less memory storage.

The bus 210 from the microprocessor and the data store is connected to one or more communication modules 220. For example, one communication module may be a TCP/IP-USB conversion module 225. As will be described in greater detail herein, the TCP/IP-USB conversion module is a bidirectional module that transforms data that conforms to the TCP/IP protocol (“TCP/IP-formatted data”) into data that may be transmitted over a USB communication link, and data that is transmitted over a USB communication link into data that conforms to the TCP/IP protocol. The output from the TCP/IP-USB conversion module 225 is coupled to the USB port 105. The USB port is the typical port used to connect the portable web server to a terminal. A second communication module 228 may be provided that transforms data that conforms to the TCP/IP protocol into data conforming to another protocol that may be communicated over an optional digital port 230. If present, the digital port provides a second means of communicating with the web server program should a USB connection not be available or should an alternate connection be desired. A third communication module may be a USB hard drive (HD) emulator 235. The USB HD emulator is also coupled to the USB port 105. The USB HD emulator 235 allows a terminal connected to the portable web server to access the data store 215 as if it were an external hard drive to the terminal. Communication modules 220 may be implemented as firmware, implemented as software routines that are executed by the microprocessor, or implemented as a combination of firmware and software.

Power for the portable web server 100 is provided by the USB port of the terminal 110 to which the portable web server is connected. Those terminals that are in compliance with the USB specification provide a 5V supply with up to 500 mA of current. All of the components depicted in FIG. 2 may be enclosed within a sealed or unsealed housing (not shown) to protect the components and enable device to be easily transported. Similar housings may be found on USB flash memory devices, USB keydrives, or USB hard drives. While the form factor for these type of devices are constantly getting smaller, such devices are typically 5 cm×2 cm×7.5 mm or smaller to make the devices readily portable and to allow the devices to fit next to other connectors in adjacent USB ports on a terminal. Those skilled in the art will appreciate that other components have been omitted from the block diagram in FIG. 2. For example, additional components such as current regulators, real time clocks, memory management components, and others have been omitted for clarity.

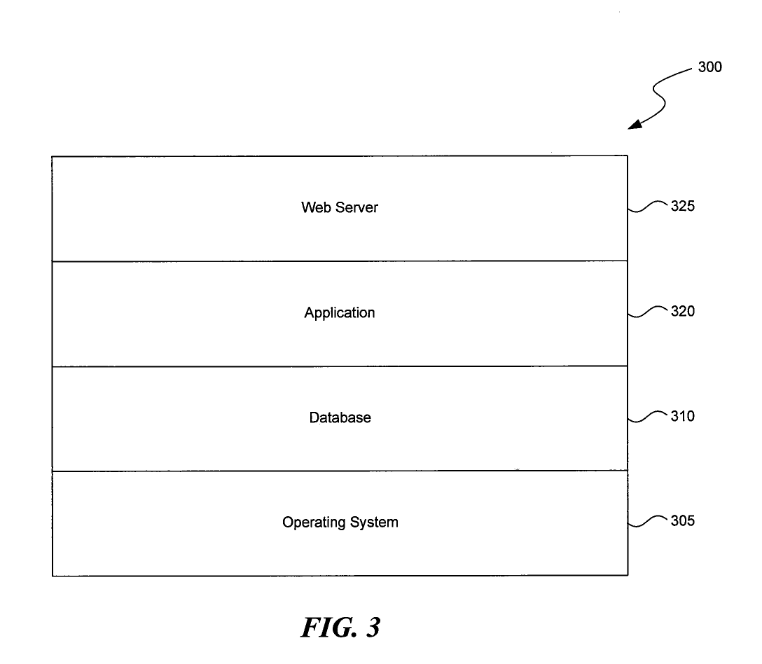

FIG. 3 is a block diagram of a representative software architecture that may be used in the portable web server 100. At the lowest level is an operating system 305 for the web server, which may be Linux or other simplified operating system for portable devices. At the next higher level are programs that implement beneficial functionality, such as a database program 310 for storing and managing data. At the next higher level, one or more web applications 320 may be stored in the portable web server. Representative applications that might be stored on the portable web server are discussed below and elsewhere in greater detail. At the highest level is a web server program 325 that is capable of sending and receiving HTTP-formatted data. Certain web servers, such as Abyss, AppWebj, Null httpd, and others, have been expressly designed to run with small resource overhead and may be suitable for use with the web server. Those skilled in the art will appreciate that certain levels and/or programs have been omitted from the software architecture 300 for clarity, and that additional levels and/or programs may be beneficially employed to implement the portable web server described herein.

While a web server program is envisioned as the primary application because of the ease of access from a terminal, other applications may be installed in addition to or in lieu of a web server program. Such installed applications may include server or client applications that communicate with a terminal using a variety of different protocols, including FTP, TFTP, IRC, POP3, and other application-level protocols in the Internet protocol suite. For example, an email application may be installed on the portable web server to enable a user to access email at a variety of different terminals.

With reference to FIGS. 2 and 3, when the portable web server 100 is connected to a terminal 110, a web application program 320 that is running on the web server may be accessed by the terminal. Access to the web application is via a web browser (e.g., Internet Explorer, Netscape, Firefox, Opera, etc.) or other program on the terminal that communicates with the web server program 325. Data is communicated between the terminal and portable web server via the USB port 105 or the digital port 230, depending on which port is utilized to connect the terminal and web server. Regardless of which physical connection is used, TCP/IP-formatted data is prepared for communication over a USB communication link by the TCP/IP-USB conversion module 225. In this fashion, the portable web server may utilize standard TCP/IP-based software while taking advantage of the large number of devices to which the web server may be connected using a USB port. Data associated with the web application program 320 may be stored on the portable web server, enabling the web application to be utilized at different terminals while accessing the same data.

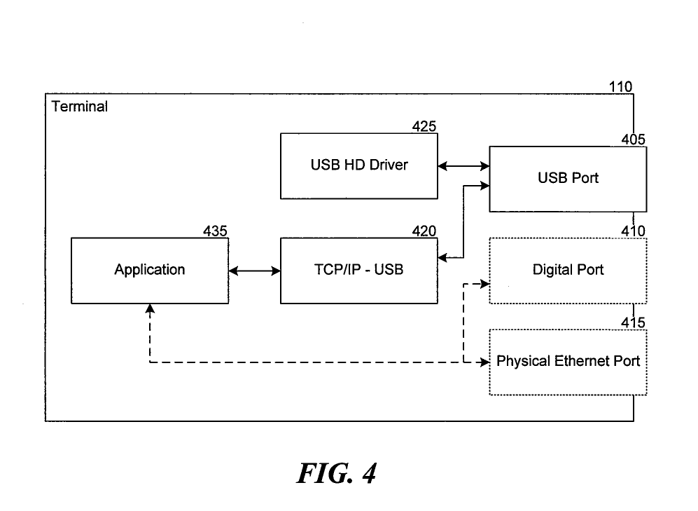

FIG. 4 is a block diagram of various components in a representative terminal 110 that enable the terminal to interface with and utilize web applications on the portable web server 100. Many of the components in the terminal mirror those that are present in the web server. For example, a USB port 405 and/or optional digital port 410 are provided in the terminal to mate with the corresponding USB port 105 and/or optional digital port 230 on the portable web server. The USB port on the terminal is typically a female port to receive the male USB port on the portable web server. In addition to the ports utilized to connect to the web server, the terminal may optionally have a physical Ethernet port 415 to allow the terminal to directly connect with public or private networks such as the Internet.

Two or more communication modules may be provided in the terminal 110. The first communication module is a bidirectional TCP/IP-USB module 420 that transforms TCP/IP-formatted data into data that may be transmitted over a USB communication link, and removes USB-formatting to recover TCP/IP-formatted data from received data. The TCP/IP-USB module is connected to the USB port 405 and also to the digital port 410. The second communication module is a USB hard drive (HD) driver 425, which allows the terminal to access the data store 215 on the portable web server as if it were an external hard drive. The USB HD driver is coupled to the USB port 405. The communication modules may be implemented as firmware, software, or a combination of firmware and software.

One or more software programs may also be provided in the terminal 110, including an application 435 that is capable of accessing a web server. In some embodiments of the terminal, the application 435 may be a web browser that allows a user of the terminal to access the web application that is executing on the portable web server. In some embodiments of the terminal, the application 435 may be a dedicated application that is designed to interface with the web application on the portable web server.

The terminal 110 may be a multi-purpose computer such as a personal computer, or a dedicated device as will be described below. Those skilled in the art will appreciate that other components have been omitted from the block diagram in FIG. 4 for clarity.

When the portable web server 100 is first connected to a terminal 110, the terminal detects the web server and loads the USB HD driver 425 in order to access the web server. A setup program is detected by the terminal in the storage area of the portable web server, and is automatically or manually downloaded to the terminal and executed by the terminal. The setup program downloads and installs the TCP/IP-USB conversion module 420 on the terminal in order to enable communication with the portable web server. Once the TCP/IP-USB conversion module is installed on the terminal, the web server and web application may be directly accessed by the terminal via communications through the USB port. It will be appreciated that rather than being downloaded from the portable web server, the necessary conversion module may be accessed remotely via the Internet or pre-installed by the terminal operator. Such alternate method may restrict the portability of the web server, however. The IP address of the portable web server may be assigned in a variety of ways: (i) the portable web server may be assigned an address within the localhost (127.0.0.0/8) address block; (ii) the portable web server may be assigned an address within the RFC 1918 address space for private networks; (iii) the portable web server may request and receive an address via DHCP, if a connection to an external network is available; and (iv) the portable web server may be assigned a static IP address, provided that potential conflicts are managed appropriately.

Because the portable web server 100 may operate in stand-alone fashion where it is not connected to the Internet or an intranet, updating the web application 320 or other software on the web server may occur with less frequency than typical web applications. One technique to update the web application or other software is to wait until the portable web server is connected to a terminal that has a broadband connection to the Internet. When the portable web server is connected to such a terminal, the web server may be able to access a manufacturer website and receive software updates such as security patches and product upgrades.

If the portable web server 100 is connected to a terminal that has access to a network such as the Internet or an intranet, various enhanced functions may also be provided by the web server. For example, the portable web server may utilize the terminal's network connection to send data to and receive data from an external web service. In this fashion, remote processing of data may be performed for the portable web server, data that is stored on the portable web server may be periodically backed-up at a remote location, or new data may be received by the portable web server. As another example, if the portable web server contains an email application program, email may be sent and received when the portable web server obtains network access. The connection to the network may be made directly for via the terminal connection. By connecting the portable web server to a network, those skilled in the art will appreciate that the capabilities of the portable web server may be enhanced in a variety of ways.

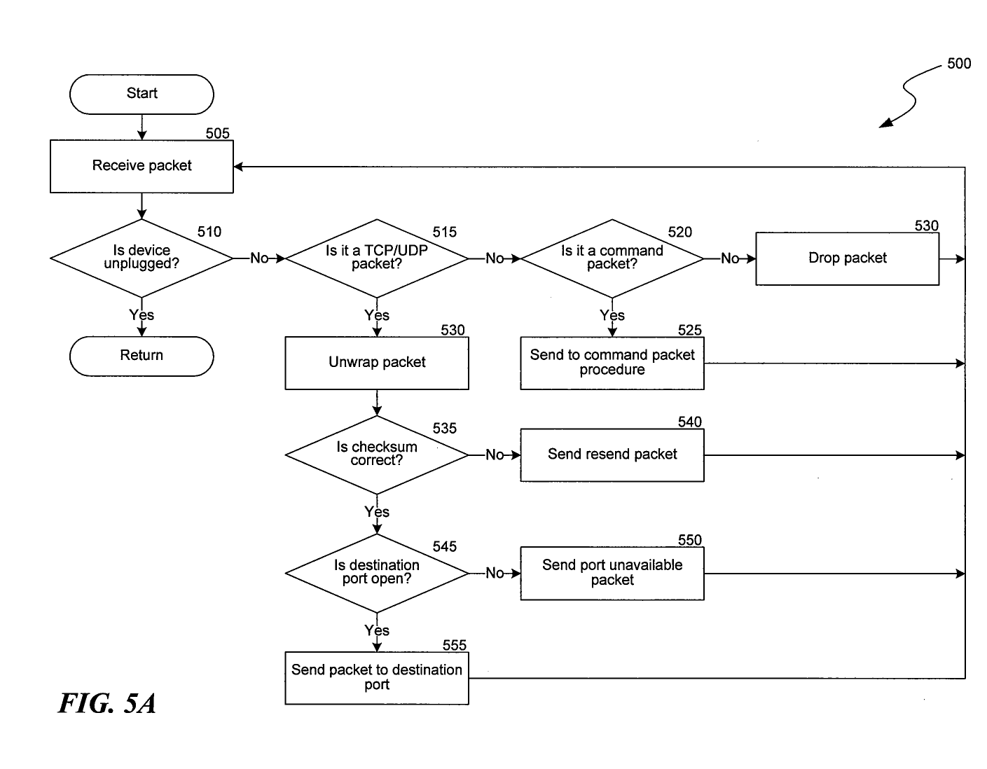

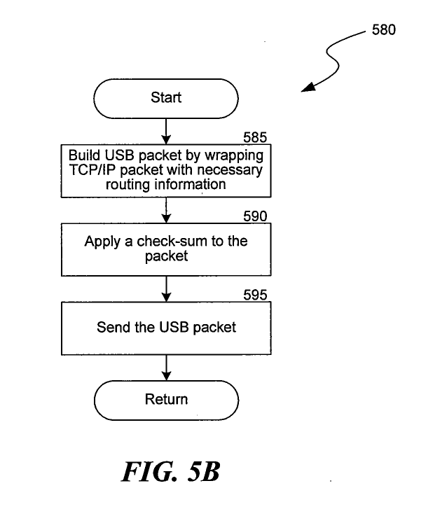

Because USB ports on computers and other devices are so ubiquitous, the web server 100 can be easily moved from terminal to terminal. To enable communication via the USB protocol, software routines are provided to enable TCP/IP-formatted packets to be communicated over USB communication links. FIG. 5A is a block diagram of a receive routine 500 to recover TCP/IP-formatted packets from data received over a USB communication link, such as may be performed by the TCP/IP-USB conversion modules 225 and 420. At a block 505, a packet is received at a terminal or at the portable web server. At a decision block 510, the TCP/IP-USB conversion module performs a test to determine whether the portable web server has been unplugged (i.e., disconnected) from the terminal. If the portable web server has been unplugged, the receive routine 500 is halted and processing on the received packet is terminated.

If the portable web server is still plugged into the terminal at decision block 510, processing continues to a decision block 515 where the TCP/IP-USB conversion module determines whether the received packet is a TCP/UDP packet by analyzing the packet header. If the received packet is not a TCP/UDP packet, then at a decision block 520 the TCP/IP-USB conversion module determines whether the packet is a command packet by analyzing the packet header. If the packet is a command packet, at a block 525 the packet if forwarded to a command packet procedure where the command is interpreted and acted upon by the terminal or the portable web server. If the packet is not a command packet, at a block 530 the packet is not processed since it is in format that is not recognized by the receive routine. After processing at blocks 525 and 530, the receive routine returns to block 505 where it waits to receive the next packet.

Returning to decision block 515, if the TCP/IP-USB conversion module determines that the packet is a TCP/UDP packet, processing continues to a block 530. At block 530, the received packet is unwrapped to remove the formatting dictated by the USB protocol and return the packet to a format that conforms with the TCP/IP protocol. Once the TCP/IP-formatted packet has been recovered, error handling is performed to ensure that the packet can be acted upon. At a decision block 535, the TCP/IP-USB conversion module calculates a checksum for the TCP/IP-formatted packet and determines if the checksum is accurate. If the checksum is incorrect, at a block 540 an error as assumed in the received packet and a “resend packet” command is sent to the transmitting terminal or portable web server to request that the packet be sent again. If the checksum is correct, at a decision block 545 the destination port is identified from the packet header and a test performed to determine whether the destination port is open (i.e., available to receive packets). If the destination port is not open, at a block 550 a message is sent to the transmitting terminal or portable web server to indicate that the desired destination port is currently unavailable. If the destination port is open, at a block 555 the packet is forwarded to the destination port. “Port” as used in this context refers to mapped software ports that are internal to the terminal or portable web server, rather than external hardware ports that enable communication between the terminal and the portable web server.

After the received packet has been forwarded to the appropriate destination port at block 555, processing returns to block 505 where the TCP/IP-USB conversion module waits to receive the next packet.

The receive routine 500 depicted in FIG. 5A is intended to process received packets. When packets are intended to be transmitted by the terminal or the portable web server, the processing of packets may be somewhat simplified. FIG. 5B is a flow chart of a send routine 580 to convert TCP/IP-formatted packets into packets that may be communicated over a USB communication link, such as may be performed by the TCP/IP-USB conversion modules 225 and 420. At a block 585, a USB packet is built by adding (or “wrapping”) a TCP/IP packet with necessary routing information. At a block 590, the TCP/IP-USB conversion module calculates and appends a check-sum to the packet. At a block 595, the USB packet is then transmitted to the intended destination. Those skilled in the art will appreciate that the send routine 580 and the receive routine 500 are complementary, and that changes impacting formatting that are made to one routine are typically reflected by changes to the other routine.

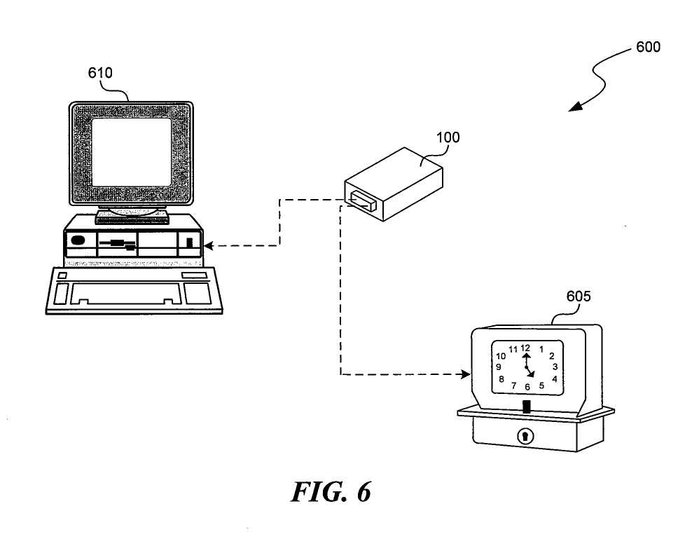

FIG. 6 is a block diagram of a representative business environment 600 where the use of a portable web server may be advantageous. The portable web server 100 is depicted as being connectable to two terminals. The first terminal is a time clock 605, such as a time clock used to track the hours worked by a company's employees. While time clocks of the past relied on a mechanically-actuated stamp to print date and time information on a heavy paper card, modern time clocks are often electronically-based. That is, the time clock may contain a digital clock, a microprocessor, and memory for recording attendance events of employees. The employee seeking to “clock in” or “clock out” may be authenticated by an employee number, magnetic card, RFID tag, biometric information (e.g., finger prints, hand scans), or other method. Once an attendance event related to an employee is captured by the time clock 605, however, it may be difficult to easily transfer the stored information to an office computer 610 for activities like payroll processing. Wired or wireless networks between the time clock and the office computer are expensive and difficult to maintain, and may not be worth the effort for small business owners that have a small number of time clocks. Even if the time clock were connected to the office computer through a network, however, the small business environment poses other challenges to time clock manufacturers. For example, the disparity in user sophistication and wide variety of office computer configurations makes it very difficult to provide software that is easy to install and maintain without requiring a significant amount of customer service support. In this type of environment, the use of a portable web server to store and manipulate employee attendance data may be particularly beneficial.

When the portable web server 100 is utilized in business environment 600, a time and attendance application is loaded on the web server as web application 320. The time clock 605 has a data acquisition and management application that is loaded on the time clock as application 435. The data acquisition and management application works in concert with the time and attendance application on the portable web server to record and store employee attendance events that are captured by the time clock. When the portable web server 100 is connected to the time clock 605, employee attendance data may be periodically or continuously transmitted from the time clock to the portable web server and stored in data store 215. When the portable web server is not connected to the time clock, employee attendance data may be queued at the time clock and delivered to the portable web server when the server is next connected to the time clock.

On a periodic basis (e.g., every other week or once a month), a payroll specialist may disconnect the portable web server 100 from the time clock 605 and connect the portable web server to an office computer 610. When connected to the office computer, the payroll specialist is able to access the time and attendance web application on the portable web server by opening the computer's browser program and connecting to the web server. The payroll specialist is able to view, manipulate, and complete the payroll processing utilizing the application on the web server. Functionality may be provided to allow the data stored in the portable web server to be downloaded to the office computer for archival purposes, or uploaded to a remote server via an Internet connection maintained by the office computer. Accessing the attendance data in this fashion provides a high degree of data security, as the physical possession of the portable web server is required to access the data. Accessing the data in this fashion also ensures that any computer with a standard browser would be able to utilize the time and attendance application.

Rather than access the web application on the portable web server using a browser, in some embodiments the office computer 610 may include a dedicated time and attendance application that interfaces with the time and attendance application on the web server. The dedicated application on the office computer may provide enhanced capabilities that are not available to users of the web application on the portable web server. For example, additional reporting, tax, or other modules necessary for payroll processing may only be found on the office computer. Payroll specialists that access the web application using the dedicated application will therefore be able to complete more sophisticated operations that those that access the web application using only a browser.

In some embodiments, various security features may be implemented in association with the portable web server in order to further protect the application and data that is contained on the server. For example, access to the application and data may be password protected to ensure that only authorized users are able to access the time and attendance functionality. As another example, the time clock 605 may have a special locking access door, so that the portable web server 100 cannot be disconnected from the time clock without having possession of the appropriate key. As yet another example, the data may be encrypted on the portable web server so that it is difficult for someone in possession of the portable web server to access the data without the encryption key. As still another example, the data exchanged between a portable web server and a terminal may be encrypted. Those skilled in the art will appreciate that other features may be implemented on the office computer, time clock, and portable web server to further enhance the security of the system.

While the use of the portable web server has been depicted with a time clock in a business environment, it will be appreciated that there are a significant number of other environments in which the portable web server may be used. The portable web server may be used in environments where it is beneficial to store data on the web server. Such uses may include, among other uses, implementing a CRM system, managing contact lists, managing email, and implementing patient records in medical facilities. For example, a user may carry an email application and their stored email with them, so that they may access their stored email at any terminal. The portable web server may also be used in environments where it is beneficial to perform certain processing in a secure fashion. Such uses may include processing using certain proprietary algorithms. For example, a portable web server may contain proprietary routines for determining optimum pricing of a catalog of products based on historical purchase patterns. In this case, certain purchase data could be provided to the portable web server for processing and the results of the processing delivered back to the terminal in a manner that protects the algorithms used in the processing. As another example, a portable web server may contain proprietary routines for implementing a voice over IP (VoIP) service. The example environment described herein where the portable web server is used with a time clock is therefore not intended to limit the application of this technology in any way.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above detailed description of embodiments of the system is not intended to be exhaustive or to limit the system to the precise form disclosed above. While specific embodiments of, and examples for, the system are described above for illustrative purposes, various equivalent modifications are possible within the scope of the system, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, or may be performed at different times.

The teachings of the methods and system provided herein can be applied to other systems, not necessarily the system described above. The elements and operation of the various embodiments described above can be combined to provide further embodiments.

While certain aspects of the technology are presented below in certain claim forms, the inventors contemplate the various aspects of the technology in any number of claim forms. For example, while only one aspect of the invention is recited as embodied in a computer-readable medium, other aspects may likewise be embodied in a computer-readable medium. Accordingly, the inventors reserve the right to add additional claims after filing the application to pursue such additional claim forms for other aspects of the technology.

We claim:

1. A portable web server capable of being coupled and decoupled to a terminal via a universal serial bus connector, the portable web server comprising:
a storage area for storing a web server program that accepts HTTP requests and serves HTTP responses in response to the requests;
a processor coupled to the storage area for executing the web server program; and
a universal serial bus (USB) connector for coupling to a complementary USB connector on a terminal and creating a universal serial bus between the portable web server and the terminal, wherein HTTP requests are received from the terminal via the universal serial bus and delivered to the web server program and HTTP responses from the web server program are served to the terminal via the universal serial bus and wherein power is provided to the portable web server via the universal serial bus.

2. The portable web server of claim 1, further comprising a communications interface coupled to the universal serial bus, the communications interface converting data formatted for transmission over the universal serial bus into data formatted in accordance with the TCP/IP protocol.

3. The portable web server of claim 2, wherein the communications interface further converts data formatted in accordance with the TCP/IP protocol into data formatted for transmission over the universal serial bus.

4. The portable web server of claim 1, wherein the USB connector may be coupled to the terminal without the use of a cable between the portable web server and the terminal.

5. The portable web server of claim 1, further comprising a web application that is accessible via the web server program.

6. The portable web server of claim 5, wherein the web application is a time and attendance application.

7. The portable web server of claim 5, wherein the web application stores application data in the storage area.

8. The portable web server of claim 1, further comprising a housing that substantially encloses the processor, storage area, and USB connector.

9. A method of accessing a web application contained on a web server at one or more terminals, the method comprising:
connecting a web server to a terminal via a connector containing a universal serial bus, the web server being powered by the universal serial bus and executing a web server program and a web application that are stored in a data store on the web server;
executing a browser program on the terminal; and
accessing the web application on the web server via the browser program on the terminal.

10. The method of claim 9, wherein the web server is directly connected to the terminal without the use of a cable.

11. The method of claim 9, further comprising:
disconnecting the web server from the terminal;
connecting the web server to a second terminal;
executing a browser program on the second terminal; and
accessing the web application via the browser program on the second terminal.

12. The method of claim 9, wherein a startup program is downloaded from the web server to the terminal when the web server is first connected to the terminal.

13. The method of claim 12, wherein the startup program installs a communication module on the terminal.

14. The method of claim 13, wherein the communication module converts data formatted for communication over the universal serial bus into data formatted in accordance with the TCP/IP protocol.

15. The method of claim 13, wherein the communication module converts data formatted in accordance with the TCP/IP protocol into data formatted for communication over the universal serial bus.

16. The method of claim 9, further comprising storing data from the web application in the data store.

17. A portable web server capable of being coupled and decoupled to a terminal via a universal serial bus connector, the portable web server comprising:
a storage area for storing a web server program and a time and attendance web application;
a processor coupled to the storage area for executing the web server program and the time and attendance web application; and
a universal serial bus (USB) connector for coupling to a complementary USB connector on a terminal and creating a universal serial bus between the portable web server and the terminal, wherein the time and attendance web application may be accessed from the terminal using HTTP requests and HTTP responses that are received and sent via the universal serial bus.

18. The portable web server of claim 17, wherein the terminal is a time clock.

19. The portable web server of claim 17, wherein the terminal is a personal computer.

20. The portable web server of claim 19, wherein the time and attendance web application is accessed using a web browser.

21. The portable web server of claim 17, further comprising a communications interface coupled to the universal serial bus, the communications interface converting data formatted for transmission over the universal serial bus into data formatted in accordance with the TCP/IP protocol.

22. The portable web server of claim 21, wherein the communications interface further converts data formatted in accordance with the TCP/IP protocol into data formatted for transmission over the universal serial bus.

23. The portable web server of claim 17, wherein power for the portable web server is provided by the terminal.

24. The portable web server of claim 23, wherein the power is provided via the universal serial bus.

25. The portable web server of claim 17, wherein the USB connector may be coupled to the terminal without the use of a cable between the portable web server and the terminal.

26. The portable web server of claim 17, wherein the time and attendance web application stores data in the storage area.

27. The portable web server of claim 17, further comprising a housing that substantially encloses the processor, storage area, and USB connector.
